(19) United States
(12) Patent Application Publication
(10) Pub. No.: US 2012/0104920 A1
(43) Pub. Date: May 3, 2012

(54) CONTAINER DATA CENTER

(75) Inventors: WEN-TANG PENG, Tu-Cheng (TW); YI-LIANG HSIAO, Tu-Cheng (TW)

(73) Assignee: HON HAI PRECISION INDUSTRY CO., LTD., Tu-Cheng (TW)

(21) Appl. No.: 12/969,475

(22) Filed: Dec. 15, 2010

(30) Foreign Application Priority Data
Oct. 29, 2010 (TW) 99137383

(51) Int. Cl. H05K 5/02; A47B 88/16; A47B 88/04

(52) U.S. Cl. 312/334.28; 312/334.27

(57) ABSTRACT

A container data center includes a portable container, two supports, two first slide rails, and a rack. The container includes a top wall and a bottom wall opposite to the top wall. The supports are formed on the bottom wall facing the top wall. The first slide rails are formed on tops of the supports. The rack includes two rows of slide portions formed on a bottom plate, each row of slide portions slidably resist against the first slide rail of a corresponding support. Thereby, the rack is slidably received in the container.

### CROSS-REFERENCE OF RELATED APPLICATION

A relevant subject matter is disclosed in a co-pending U.S. patent application, entitled “CONTAINER DATA CENTER”, with application Ser. No. 12/965,713, filed on Dec. 10, 2010, which is assigned to the same assignee as this present application.

### BACKGROUND

1. Technical Field

The present disclosure relates to a container data center.

2. Description of Related Art

With increasing heavy duty use of on-line applications, the need for computer data centers has increased rapidly. Data centers are centralized computing facilities that include a portable container, many server racks or shelves received in the container and many servers arranged on server racks or shelves, and one rack or shelf with some servers can be considered a server system. However, the receiving space of the container is rather limited, and the server system is very heavy, making it difficult to install the server system in the container.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric, cutaway view of an exemplary embodiment of a container data center, the container data center including a rack and a container with two supports.

FIG. 2 is a partial, enlarged view of the rack of FIG. 1, but showing an inverted view of FIG. 1.

FIG. 3 is an enlarged view of one of the supports of FIG. 1.

FIG. 4 is an assembled, isometric view of FIG. 1, but viewed from another perspective.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

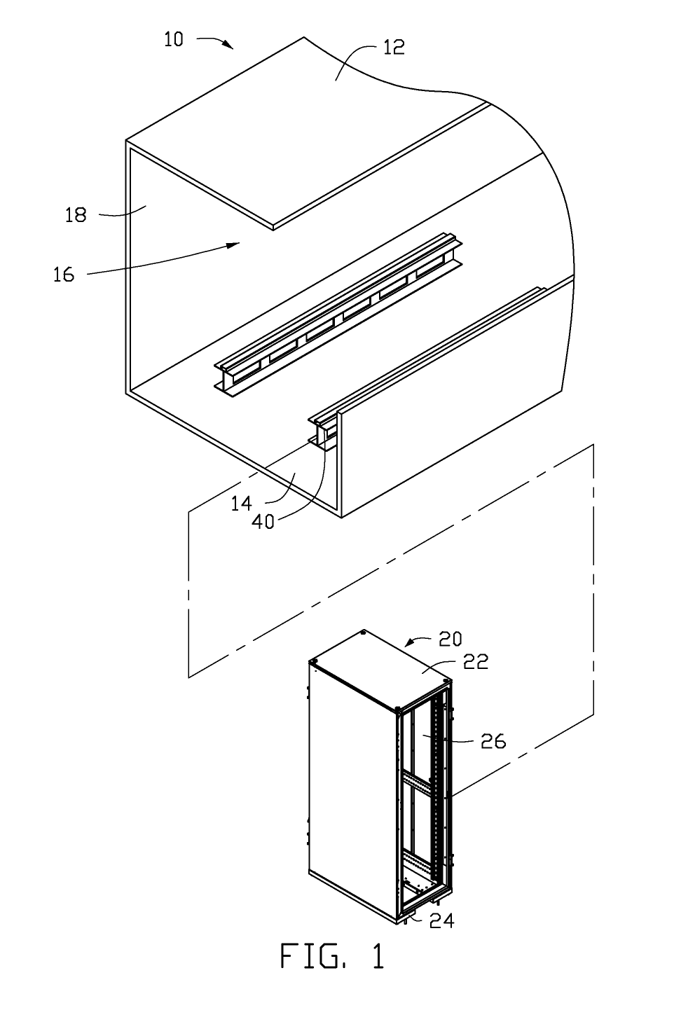

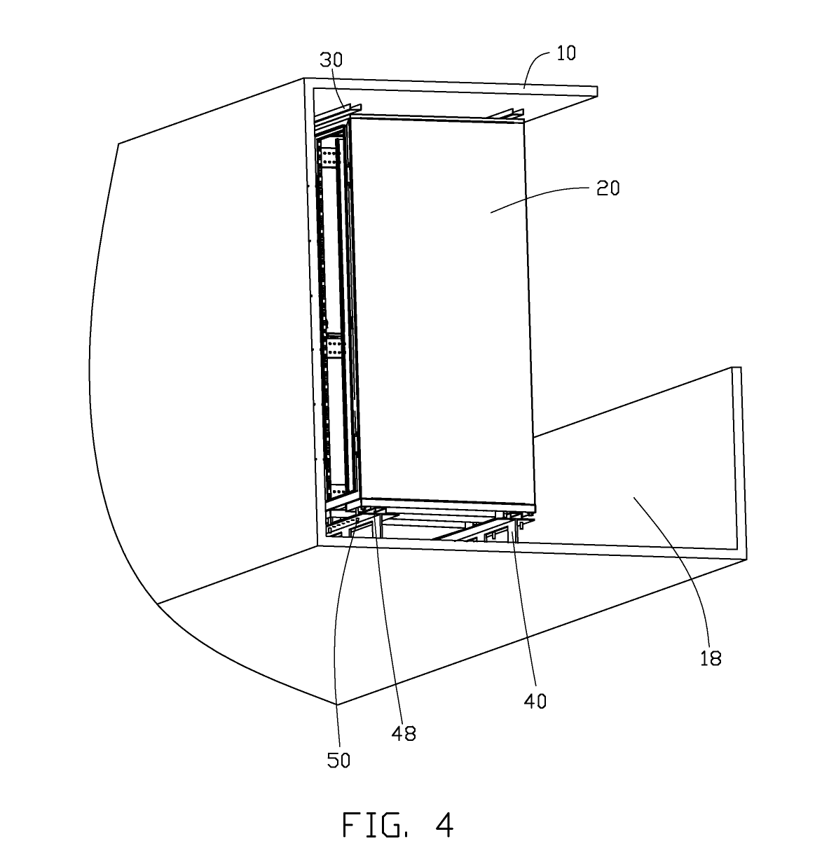

Referring to FIGS. 1 and 4, an embodiment of a container data center includes a portable container 10, and a rack 20. The container 10 includes a top wall 12, and a bottom wall 14 opposite to the top wall 12. A receiving space 16 is bounded by the top wall 12 and the bottom wall 14. An inlet 18 communicating with the receiving space 16 is bounded by corresponding ends of the top wall 12 and the bottom wall 14. The container 10 further includes two slide rails 30 and two supports 40 corresponding to the slide rails 30. The slide rails 30 are attached in parallel to an inner surface of the top wall 12, facing the bottom wall 14. The supports 14 are attached to an inner surface of the bottom wall 14, facing the top wall 12.

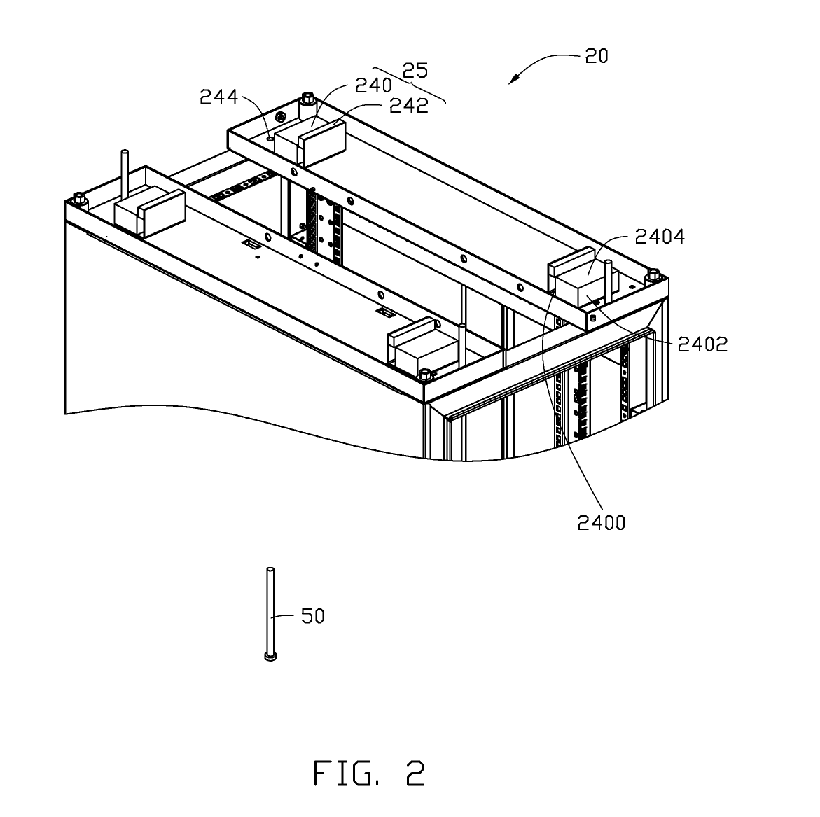

Referring to FIG. 2, the rack 20 includes a substantially rectangular top plate 22, and a substantially rectangular bottom plate 24 opposite to the top plate 22. A receiving space 26 is bounded by the top plate 22 and bottom plate 24, to receive servers, power sources, and heat dissipation devices.

Two rows of slide portions 25 are formed on opposite sides of a bottom of the bottom plate 24. Each row of slide portions 25 includes two slide portions 25. Each slide portion 25 includes a substantially rectangular slide block 240 and a limiting block 242 at a side of the slide block 240 facing the other slide portion 25. The slide blocks 240 cooperatively form a rectangle, and each slide block 240 is positioned at a point of the rectangle. Each slide block 240 includes a first side surface 2400 facing the slide block 240, a second side surface 2402 opposite to the first side surface 2400, and a slide surface 2404 substantially perpendicularly connected between bottoms of the first and second side surfaces 2400 and 2402. Each limiting block 242 is adjacent to the first side surface 2400 of the corresponding slide block 240. The bottom plate 24 further defines four through holes 244. Each through hole 244 is positioned at a side of the second side surface 2402 of the corresponding slide block 240.

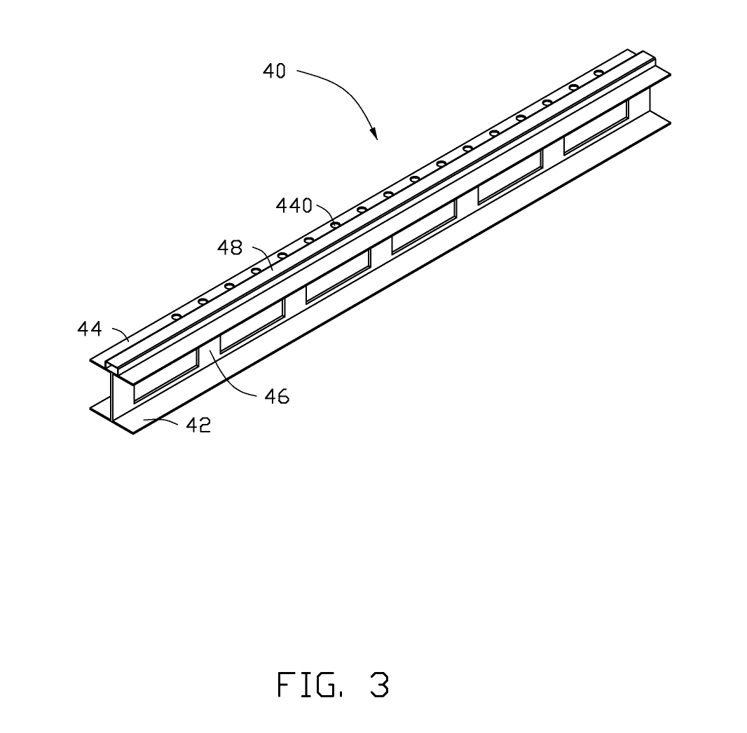

Referring to FIG. 3, each support 40 is substantially I-shaped and includes a lower support plate 42, an upper support plate 44 opposite to the lower support plate 42, and a plurality of connection plates 46 substantially perpendicularly connected between center lines of the lower and upper support plates 42 and 44. The lower support plate 42 is mounted on the bottom wall 14. A slide rail 48 longitudinally protrudes from the upper support plate 44. The upper support plate 44 defines a plurality of mounting holes 440 at a side of the slide rail 48.

Referring to FIG. 4, in assembly, the rack 20 is placed in the receiving space 16 of the container 10 through the inlet 18. The top plate 22 of the rack 20 slidably resists against the slide rails 30. The slide surfaces 2404 of the slide portions 25 slidably resist against top surfaces of the slide rails 48 of the supports 40, and the limiting blocks 242 slidably resist against side surfaces of the slide rails 48 far away from the corresponding mounting holes 440. Thus, the rack 20 is slidably received in the container 10. When the rack 20 is moved along the slide rails 30 and 48 to a predetermined position, a plurality of fasteners 50, such as bolts, are extended through the through holes 244 of the rack 20 and engage in the corresponding mounting holes 440 of the slide rail 48 to tightly mount the rack 20 in the container 10.

In this embodiment, the slide blocks 240 and the limiting blocks 242 are made of polyoxymethylene, which can effectively reduce friction between the rack 20 and the slide rails 48.

It is to be understood, however, that even though numerous characteristics and advantages of the embodiments have been set forth in the foregoing description, together with details of the structure and function of the embodiments, the present disclosure is illustrative only, and changes may be made in details, especially in matters of shape, size, and arrangement of parts within the principles of the embodiments to the full extent indicated by the broad general meaning of the terms in which the appended claims are expressed.

1. A container data center comprising:
a portable container comprising a top wall and a bottom wall opposite to the top wall;
two supports formed on the bottom wall facing the top wall;
a first slide rail formed on a top of each of the supports facing the top wall; and
a rack slidably received in the container;
wherein the rack comprises two rows of slide portions formed on a bottom plate of the rack, each row of slide portions slidably resist against the first slide rail of a corresponding support.

2. The container data center of claim 1, wherein two second slide rails are formed on an inner surface of the top wall facing the bottom wall, a top plate of the rack slidably resists against the second slide rails.

3. The container data center of claim 2, wherein the bottom plate of the rack is substantially rectangular, two rows of the slide portions are formed on opposite sides of a bottom of the bottom plate to resist against the corresponding first slide rails.

4. The container data center of claim 3, wherein each row of slide portions comprises two slide portions resisting against a same first slide rail.

5. The container data center of claim 4, wherein each slide portion comprises a slide block slidably resisting against a top surface of the corresponding first slide rail, and a limiting block located at a side of the slide block and slidably resisting against a side surface of the corresponding first slide rail.

6. The container data center of claim 5, wherein each slide block comprises a first side surface facing the corresponding slide block, a second side surface opposite to the first side surface, and a slide surface substantially perpendicularly connected between bottoms of the first and second side surfaces; wherein each limiting block is adjacent to the first side surface of the corresponding slide block, and the slide surface slidably resists against the top surface of the corresponding first rail.

7. The container data center of claim 6, wherein the bottom plate of the rack defines four through holes each positioned at a side of the corresponding slide block opposite to the limiting block, and each support longitudinally defines a plurality of mounting holes, four fasteners extend through the corresponding through holes and engage in the corresponding mounting holes to tightly mount the rack in the container.

8. The container data center of claim 5, wherein the slide block and limiting block are made of the polyoxymethylene.

9. The container data center of claim 1, wherein each support is substantially I-shaped.

10. The container data center of claim 9, wherein each support comprise a lower support plate mounted on the bottom wall of the container, an upper support plate opposite to the lower support plate, and a plurality of connection plates substantially perpendicularly connected between center lines of the lower and upper support plates; wherein the first slides rail are formed on top surfaces of the corresponding upper support plates.
